(19) United States
(12) Patent Application Publication
(10) Pub. No.: US 2026/0020162 A1
(43) Pub. Date: Jan. 15, 2026

(54) SUBSTRATE STRUCTURE AND METHOD OF MANUFACTURING THE SAME

(71) Applicant: CHIPBOND TECHNOLOGY CORPORATION, Hsinchu City (TW)

(72) Inventors: Sheng-Jen Wu, Hsinchu County (TW); Shih-Chung Chang, Taichung City (TW); Chun-Te Lee, Hsinchu County (TW); Hsueh-Shun Yeh, Hsinchu County (TW)

(21) Appl. No.: 19/095,222

(22) Filed: Mar. 31, 2025

(30) Foreign Application Priority Data
Jul. 9, 2024 (TW) 113125729

(51) Int. Cl. H05K 3/40; H05K 1/11

(52) U.S. Cl. CPC H05K 3/4007; H05K 1/111

(57) ABSTRACT

A substrate structure includes a substrate, UBMs and tapered micro bumps. A passivation layer of the substrate has a passivation opening, and a pad is visible from the passivation opening. A recession of each of UBMs is formed in the passivation opening and electrically connected to the pad. A root of each of the tapered micro bumps is located in the recession, and a contacting portion of each of the tapered micro bumps protrudes the recession. Each of the tapered micro bumps includes an insulating tapered part, a conductive layer and a bonding layer. The conductive layer covers the insulating tapered part and is electrically connected to the UBM. The bonding layer covers the conductive layer and is electrically connected to the conductive layer. The maximum outer diameter of each of the tapered micro bumps is not greater than 20 μm.

### CROSS-REFERENCE TO RELATED APPLICATIONS

This application claims priority to R.O.C patent application No. 113125729 filed Jul. 9, 2024, the disclosure of which is hereby incorporated by reference in its entirety.

### FIELD OF THE INVENTION

This invention relates to a substrate structure and its manufacturing method, and more particularly to a substrate structure and a manufacturing method in which tapered micro bumps are formed on pads of a substrate.

### BACKGROUND OF THE INVENTION

Conventional semiconductor package includes a circuit board and a chip which is bonded to the circuit board via bumps. Fine-pitch pads on the circuit board and chip are necessary to meet miniaturization requirement of the semiconductor package, but it comes with bridge connection of bumps to lower the semiconductor package reliability.

### SUMMARY OF THE INVENTION

One object of the present invention is to provide a substrate structure having micro bumps and its manufacturing method in which more bumps can be provided without the issue of bridge connection between bumps. Thus, the substrate structure of the present invention can be electrically connected to another electronic element, e.g. ITO film, using the micro bumps.

A method of manufacturing a substrate structure includes the steps as follows. A step of providing a substrate which includes a carrier, a circuit layer and a passivation layer, the circuit layer is formed on the carrier, covered by the passivation layer and has pads, and the pads are visible from passivation openings of the passivation layer. A step of forming a first metal layer, the first metal layer covers the passivation layer and the pads located in the passivation openings, the first metal layer has recessions, each of the recessions is formed in one of the passivation openings and is electrically connected to one of the pads. A step of forming an insulating layer, the insulating layer covers the first metal layer and fills the recessions. A step of patterning the insulating layer to form an insulating tapered part in each of the recessions, the first metal layer located around the insulating tapered part is visible, and the insulating tapered part has a base located in the recession and a terminal protruding the recession. A step of forming a second metal layer, the second metal layer covers the insulating tapered part and the first metal layer located around the insulating tapered part, and the second metal layer is electrically connected to the first metal layer. A step of forming a photoresist layer, the photoresist layer covers the second metal layer. A step of patterning the photoresist layer to form openings, the second metal layer covering each of the insulating tapered parts is visible from one of the openings. A step of forming a bonding layer in each of the openings, the bonding layer covers the second metal layer located in each of the openings and is electrically connected to the second metal layer, a thickness of the bonding layer is greater than that of the second metal layer. A step of removing the photoresist layer, the bonding layer and the second metal layer not covered by the bonding layer are visible. A step of removing the first and second metal layers not covered by the bonding layer using the bonding layer as a mask, the second metal layer becomes conductive layers, the first metal layer located under the insulating tapered parts becomes UBMs, each of the UBMs has one of the recessions. The insulating tapered part, the conductive layer and the bonding layer form a tapered micro bump, and the maximum outer diameter of the tapered micro bump is less than or equal to 20 μm along a first direction.

A substrate structure of the present invention includes a substrate, UBMs and tapered micro bumps. The substrate includes a carrier, a circuit layer and a passivation layer. The circuit layer is formed on the carrier and has pads. The passivation layer covers the circuit layer and has passivation openings, each of the pads can be visible from one of the passivation openings. Each of the UBMs is formed in one of the passivation openings and has a recession located in the passivation opening, and the recession is electrically connected to the pad. Each of the tapered micro bumps includes an insulating tapered part, a conductive layer and a bonding layer. The insulating tapered part is formed on the recession and includes a base located in the recession and a terminal protruding the recession. The conductive layer covers the insulating tapered part and is electrically connected to the UBM. The bonding layer covers the conductive layer and is electrically connected to the conductive layer, and the bonding layer is thicker than the conductive layer. The maximum outer diameter of each of the tapered micro bumps is not greater than 20 μm along a first direction.

The recession of the UBM is provided in the passivation opening, and the tapered micro bump is formed in the passivation opening. The tapered micro bump is electrically connected to the UBM via the conductive layer covering the insulating tapered part. The bonding layer covers the conductive layer and is electrically connected to the conductive layer. The present invention can miniature the tapered micro bumps to improve the amount and density of bumps on the substrate structure and reduce the pitch of the tapered micro bumps. Consequently, the substrate structure of the present invention can be bonded to another electronic element with fine-pitch pads via the tapered micro bumps.

### BRIEF DESCRIPTION OF DRAWINGS

FIGS. 1 to 10 are cross-section view diagrams illustrating a method of manufacturing a substrate structure in accordance with one embodiment of the present invention.

### DETAILED DESCRIPTION OF THE INVENTION

With reference to FIG. 1, in a method of manufacturing a substrate structure 100 in accordance with one embodiment of the present invention, a substrate 110, which may be a wafer or a glass substrate, is provided firstly. The substrate 110 includes a carrier 111, a circuit layer 112 and a passivation layer 113. The circuit layer 112 is formed on the carrier 111 and has pads 112a. The passivation layer 113 covers the circuit layer 112 and has passivation openings 113a, each of the pads 112a is visible from one of the passivation openings 113a.

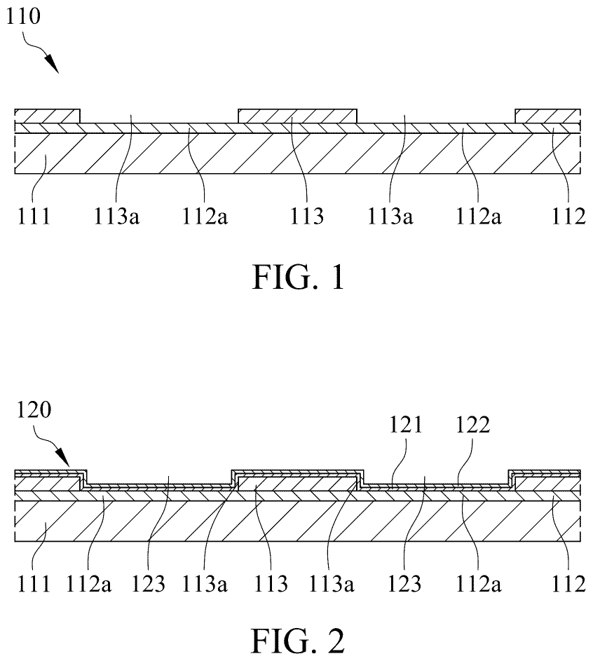

With reference to FIG. 2, then a first metal layer 120 is formed. The first metal layer 120 covers the passivation layer 113 and the pads 112a located in the passivation openings 113a. The first metal layer 120 has multiple recessions 123, each of the recessions 123 is located in one of the passivation openings 113a and electrically connected to the pad 112a located in the passivation opening 113a. In this embodiment, the first metal layer 120 at least involves a first portion 121 and a second portion 122, the first portion 121 covers the passivation layer 113 and the pads 112a, and the second portion 122 covers the first portion 121. Preferably, the first and second portions 121 and 122 of the first metal layer 120 are formed on the passivation layer 113 through sputtering process, the first portion 121 can be made of titanium (Ti) or titanium alloy, and the second portion 122 can be made of gold (Au) or gold alloy.

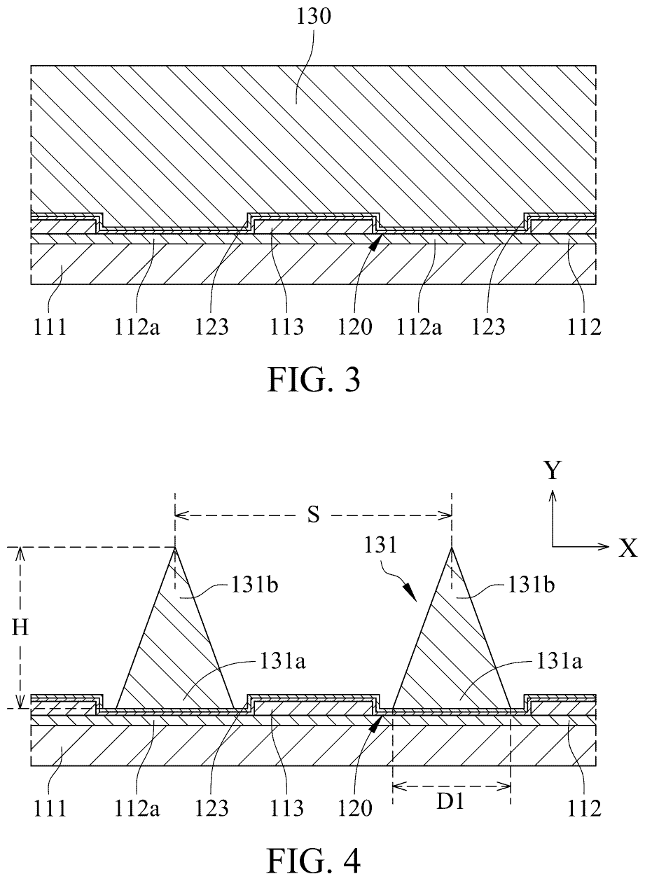

With reference to FIG. 3, an insulating layer 130 is formed after forming the first metal layer 120. The insulating layer 130 covers the first metal layer 120 and fills in the recessions 123 of the first metal layer 120. Preferably, the insulating layer 130 is coated on the first metal layer 120, and it can be made of polymer material, such as polyimide (PI) or other insulating material.

Referring to FIG. 4, next, the insulating layer 130 is patterned to form an insulating tapered part 131 on each of the recessions 123 of the first metal layer 120. Preferably, the insulating layer 130 is patterned through exposure, development, and baking processes. After patterning process, the insulating layer 130 on each of the recessions 123 is retained, others are removed, and the first metal layer 120 located around the insulating tapered part 131 is visible. A base 131a of the insulating tapered part 131 is located on the recession 123, a terminal 131b of the insulating tapered part 131 protrudes the recession 123, and an outer diameter of the insulating tapered part 131 is reduced gradually from the base 131a to the terminal 131b. Along a first direction X, a maximum outer diameter D1 of the insulating tapered part 131 is not greater than 8 μm, and a distance S between the terminals 131b of the adjacent insulating tapered parts 131 is not greater than 100 μm. A height H of the insulating tapered part 131 is not greater than 20 μm in a second direction Y which is perpendicular to the first direction X.

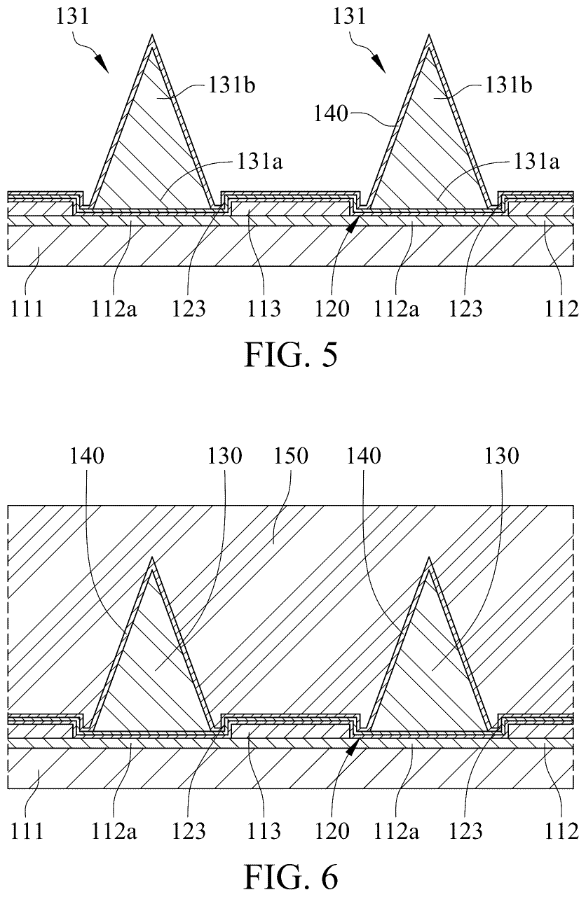

With reference to FIG. 5, a second metal layer 140 is formed after patterning the insulating layer 130. The second metal layer 140 covers the insulating tapered parts 131 and the first metal layer 120 located around the insulating tapered parts 131, and the second metal layer 140 is electrically connected to the first metal layer 120. Preferably, the second metal layer 140 is formed on the insulating tapered parts 131 and the first metal layer 120 through sputtering process, and it can be made of gold or gold alloy. In this embodiment, the second portion 122 of the first metal layer 120 and the second metal layer 140 are made of the same metallic material.

With reference to FIG. 6, after forming the second metal layer 140, a photoresist layer 150 is formed to cover the second metal layer 140. Preferably, the photoresist layer 150, which can be positive photoresist or negative photoresist, is coated on the second metal layer 140.

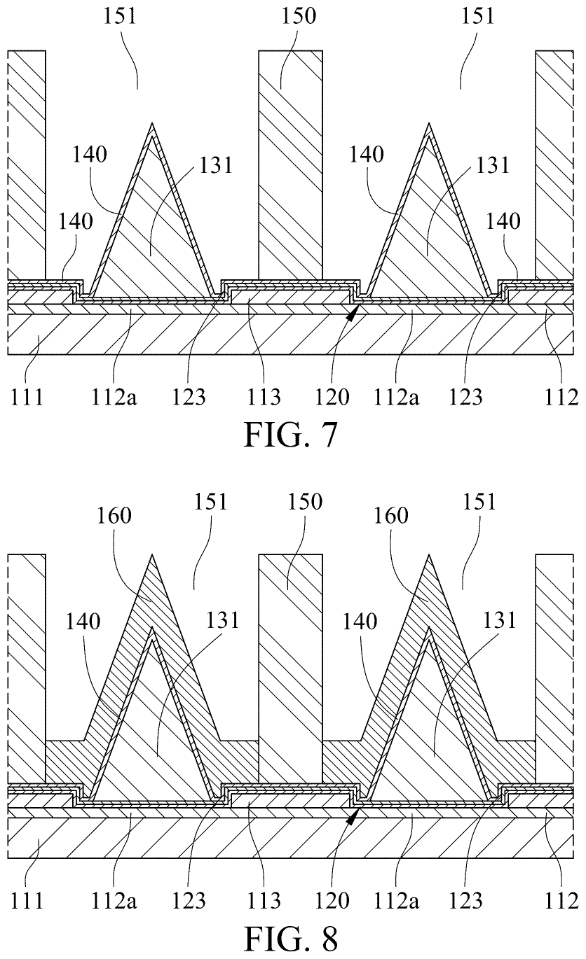

With reference to FIG. 7, next, the photoresist layer 150 is patterned to have multiple openings 151. The second metal layer 140 covering each of the insulating tapered parts 131 is visible from one of the openings 151. In this embodiment, the second metal layer 140 located around each of the insulating tapered parts 131 is also visible from the opening 151. Preferably, the photoresist layer 150 is patterned through photolithography, and photoresist residues remaining in the openings 151 can be removed by plasma descum to protect the second metal layer 140 from contamination.

With reference to FIG. 8, a bonding layer 160 is formed in each of the openings 151 after patterning the photoresist layer 150. The bonding layer 160 covers the second metal layer 140 located in each of the openings 151 and it is electrically connected to the second metal layer 140. The thickness of the bonding layer 160 is greater than that of the second metal layer 140. Preferably, the bonding layer 160, may be made of gold or gold alloy, is plated on the second metal layer 140, and in this embodiment, the bonding layer 160 and the second metal layer 140 are made of the same metallic material.

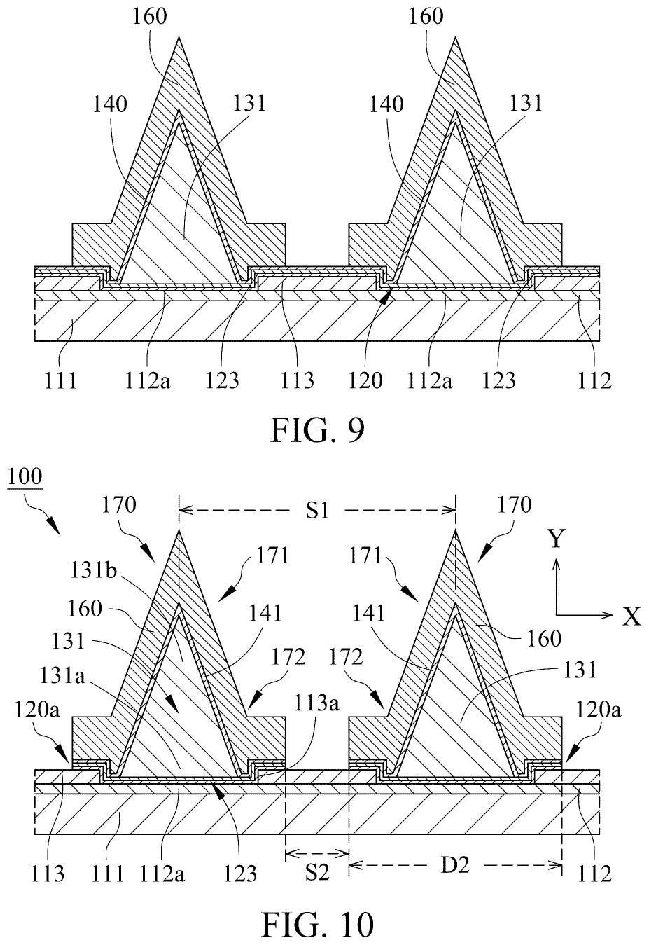

With reference to FIG. 9, after forming the bonding layer 160, the patterned photoresist layer 150 is removed, and the bonding layer 160 and the second metal layer 140 not covered by the bonding layer 160 are visible.

With reference to FIG. 10, finally, the bonding layer 160 is used as a mask during removing the first metal layer 120 and the second metal layer 140 not covered by the bonding layer 160. After removing the exposed metal layers, the retained second metal layer 140 becomes multiple conductive layers 141, the retained first metal layer 120 located under the insulating tapered parts 131 becomes multiple under bump metallizations (UBMs) 120a, and each of the UBMs 120a has one recession 123. The insulating tapered part 131, the conductive layer 141 covering the insulating tapered part 131 and the bonding layer 160 covering the conductive layer 141 form a tapered micro bump 170. A contacting portion 171 of the tapered micro bump 170, which is used to be electrically connected to another electronic element, protrudes the recession 123, and a root 172 of the tapered micro bump 170 is located in the recession 123.

With reference to FIG. 10, the outer diameter of the tapered micro bump 170 is reduced gradually from the root 172 to the contacting portion 171, and a maximum outer diameter D2 of the tapered micro bump 170 is designed to be less than or equal to 20 μm along the first direction X to meet miniaturization requirement of the tapered micro bump 170.

With reference to FIG. 10, along the first direction X, a first distance S1 between the contacting portions 171 of the adjacent tapered micro bumps 170 is not less than 4 μm, and a second distance S2 between the roots 172 of the adjacent tapered micro bumps 170 is not less than 1 μm. The first distance S1 is increased gradually from the substrate 110 toward outside in the second direction Y.

The substrate structure 100 manufactured by the method mentioned above includes the substrate 110, the UBMs 120a and the tapered micro bumps 170. Each of the UBMs 120a is formed in one of the passivation openings 113a of the passivation layer 113, and the recession 123 of each of the UBMs 120a is electrically connected to the pad 112a. Each of the UBMs 120a involves the first portion 121 and the second portion 122, the first portion 121 covers the passivation layer 113 and each of the pads 112a, and the second portion 122 covers the first portion 121. Each of the tapered micro bumps 170 includes the insulating tapered part 131, the conductive layer 141 and the bonding layer 160. The insulating tapered part 131 is formed on the recession 123, the base 131a of the insulating tapered part 131 is located in the recession 123, and the terminal 131b of the insulating tapered part 131 protrudes the recession 123. The conductive layer 141 covers the insulating tapered part 131 and is electrically connected to the UBM 120a. The bonding layer 160 covers the conductive layer 141 and is electrically connected to the conductive layer 141. Preferably, the bonding layer 160, the conductive layer 141 and the second portion 122 of the UBM 120a are made of the same metallic material.

As shown in FIG. 10, due to the tapered micro bump 170 is provided on the recession 123 which is formed on the pad 122a, the size and pitch of the tapered micro bumps 170 can be miniatured to increase the amount and density of bumps on the substrate structure 100. The substrate structure 100 can be bonded to another electronic element with fine-pitch pads via the tapered micro bumps 170. Furthermore, the first distance S1 between the contacting portions 171 of the adjacent tapered micro bumps 170 is increased gradually from the substrate 110 toward outside, so short circuit caused by bridge connection between the bonding layers 160 of the adjacent tapered micro bumps 170 can be prevented.

While this invention has been particularly illustrated and described in detail with respect to the preferred embodiments thereof, it will be clearly understood by those skilled in the art that is not limited to the specific features shown and described and various modified and changes in form and details may be made without departing from the scope of the claims.

1. A method of manufacturing substrate structure comprising:
providing a substrate, the substrate includes a carrier, a circuit layer and a passivation layer, the circuit layer is formed on the carrier, covered by the passivation layer and has a plurality of pads, and each of the plurality of pads is visible from one of a plurality of passivation openings of the passivation layer;
forming a first metal layer, the first metal layer covers the passivation layer and the plurality of pads located in the plurality of passivation openings, the first metal layer has a plurality of recessions, each of the plurality of recessions is formed in one of the plurality of passivation openings and is electrically connected to one of the plurality of pads;
forming an insulating layer, the insulating layer covers the first metal layer and fills the plurality of recessions;
patterning the insulating layer to form an insulating tapered part in each of the plurality of recessions, the first metal layer located around the insulating tapered part is visible, and the insulating tapered part has a base located in each of the plurality of recessions and a terminal protruding each of the plurality of recessions;
forming a second metal layer, the second metal layer covers the insulating tapered part and the first metal layer located around the insulating tapered part, and the second metal layer is electrically connected to the first metal layer;
forming a photoresist layer, the photoresist layer covers the second metal layer;
patterning the photoresist layer to form a plurality of openings, the second metal layer covering the insulating tapered part is visible from each of the plurality of openings;
forming a bonding layer in each of the plurality of openings, the bonding layer covers the second metal layer located in each of the plurality of openings and is electrically connected to the second metal layer, a thickness of the bonding layer is greater than that of the second metal layer;
removing the photoresist layer, the bonding layer and the second metal layer not covered by the bonding layer are visible; and
removing the first and second metal layers not covered by the bonding layer using the bonding layer as a mask, the second metal layer becomes a plurality of conductive layers, the first metal layer located under the insulating tapered part becomes a plurality of under bump metallizations (UBMs), each of the plurality of UBMs has one of the plurality of recessions, wherein the insulating tapered part, each of the plurality of conductive layers and the bonding layer form a tapered micro bump, and a maximum outer diameter of the tapered micro bump is less than or equal to 20 μm along a first direction.

2. The method in accordance with claim 1, wherein a distance between the terminals of the insulating tapered parts of the adjacent tapered micro bumps is less than or equal to 100 μm along the first direction.

3. The method in accordance with claim 2, wherein a height of the insulating tapered part is less than or equal to 20 μm along a second direction perpendicular to the first direction.

4. The method in accordance with claim 3, wherein a maximum outer diameter of the insulating tapered part is less than or equal to 8 μm along the first direction.

5. The method in accordance with claim 1, wherein a contacting portion of the tapered micro bump protrudes each of the plurality of recessions, a first distance between the contacting portions of the adjacent tapered micro bumps is greater than or equal to 4 μm, and the first distance is increased gradually from the substrate toward outside along a second direction perpendicular to the first direction.

6. The method in accordance with claim 5, wherein a root of the tapered micro bump is located in each of the plurality of recessions, and a second distance between the roots of the adjacent tapered micro bumps is greater than or equal to 1 μm.

7. The method in accordance with claim 1, wherein the bonding layer and the second metal layer are made of the same material.

8. The method in accordance with claim 7, wherein the first metal layer includes a first portion and a second portion, the first portion covers the passivation layer and the plurality of pads, the second portion covers the first portion, the second portion and the second metal layer are made of the same material.

9. A substrate structure comprising:
a substrate including a carrier, a circuit layer and a passivation layer, the circuit layer is formed on the carrier, covered by the passivation layer and has a plurality of pads, and each of the plurality of pads is visible from one of a plurality of passivation openings of the passivation layer;
a plurality of under bump metallizations (UBMs), each of the plurality of UBMs is formed in one of the plurality of passivation openings and has a recession, the recession of each of the plurality of UBMs is electrically connected to one of the plurality of pads; and
a plurality of tapered micro bumps each including an insulating tapered part, a conductive layer and a bonding layer, the insulating tapered part is formed on the recession and has a base located in the recession and a terminal protruding the recession, the conductive layer covers the insulating tapered part and is electrically connected to each of the plurality of UBMs, the bonding layer covers the conductive layer and is electrically connected to the conductive layer, and a thickness of the bonding layer is greater than that of the conductive layer, wherein a maximum outer diameter of each of the plurality of tapered micro bumps is less than or equal to 20 μm along a first direction.

10. The substrate structure in accordance with claim 9, wherein a distance between the terminals of the insulating tapered parts of the adjacent tapered micro bumps is less than or equal to 100 μm along the first direction.

11. The substrate structure in accordance with claim 10, wherein a height of the insulating tapered part is less than or equal to 20 μm along a second direction perpendicular to the first direction.

12. The substrate structure in accordance with claim 11, wherein a maximum outer diameter of the insulating tapered part is less than or equal to 8 μm along the first direction.

13. The substrate structure in accordance with claim 9, wherein a contacting portion of each of the plurality of tapered micro bumps protrudes the recession, a first distance between the contacting portions of the adjacent tapered micro bumps is greater than or equal to 4 μm, and the first distance is increased gradually from the substrate toward outside along a second direction perpendicular to the first direction.

14. The substrate structure in accordance with claim 13, wherein a root of each of the plurality of tapered micro bumps is located in the recession, and a second distance between the roots of the adjacent tapered micro bumps is greater than or equal to 1 μm.

15. The substrate structure in accordance with claim 9, wherein the bonding layer and the conductive layer are made of the same material.

16. The substrate structure in accordance with claim 15, wherein each of the plurality of UBMs includes a first portion and a second portion, the first portion covers the passivation layer, the second portion covers the first portion, the second portion and the conductive layer are made of the same material.
